(19) United States
(12) Patent Application Publication
(10) Pub. No.: US 2026/0318850 A1
(43) Pub. Date: Oct. 15, 2026

(54) RADIOGRAPHIC IMAGING APPARATUS

(71) Applicant: KONICA MINOLTA, INC., Tokyo (JP)

(72) Inventors: Junichiro OTAKI, Tokyo (JP); Mina TSUCHIZAWA, Tokyo (JP); Hajime ISHIMOTO, Tokyo (JP)

(73) Assignee: KONICA MINOLTA, INC., Tokyo (JP)

(21) Appl. No.: 19/640,507

(22) Filed: Apr. 7, 2026

(30) Foreign Application Priority Data
Apr. 9, 2025 (JP) 2025-064329

(51) Int. Cl. G01N 23/04; G01D 11/26; H05K 5/06

(52) U.S. Cl. CPC G01N 23/04; G01D 11/26; H05K 5/061; G01N 2223/318; G01N 2223/5055

(57) ABSTRACT

A radiographic imaging apparatus includes a radiation detector including a photoelectric conversion element and a scintillator configured to convert radiation into light and irradiate the photoelectric conversion element with the light, an electric circuit configured to drive the radiation detector and read out a signal of the photoelectric conversion element, a housing including a front surface part on which the radiation is incident and a rear surface part facing the front surface part with the radiation detector interposed therebetween, the housing being configured to house the radiation detector and the electric circuit, and a waterproof member disposed between the front surface part and the rear surface part. The waterproof member is a double-sided adhesive tape.

### CROSS-REFERENCE TO RELATED APPLICATION

The entire disclosure of Japanese Patent Application No. 2025-064329, filed on Apr. 9, 2025, including description, claims, drawings and abstract is incorporated herein by reference.

### BACKGROUND OF THE INVENTION

### TECHNICAL FIELD

The present disclosure relates to a radiographic imaging apparatus.

### DESCRIPTION OF RELATED ART

Conventionally, there is known a radiographic imaging apparatus that irradiates an object with radiation, detects an intensity distribution of radiation transmitted through the object, and captures a radiographic image. Radiographic imaging apparatuses are widely used in the medical field, the industrial field, and the like. In recent years, portable (cassette-type) radiographic imaging apparatuses that are separable from an imaging table and transportable have been developed and put into practical use. Such a radiographic imaging apparatus is called a flat panel detector (FPD) because it is panel-shaped.

The FPD includes, within a housing, a radiation detection panel configured to detect an intensity distribution of radiation and convert the intensity distribution into electric charges, an electric circuit configured to drive the radiation detection panel, and the like. The radiation detection panel includes a scintillator, a photoelectric conversion element, and the like.

Since the scintillator and the electric circuit are vulnerable to moisture, entry of liquid into the housing of the FPD may adversely affect the function of the FPD.

When the FPD is separated from an imaging table and carried to, for example, a patient's hospital room for use, a patient's body fluid may adhere to the FPD or the FPD may be cleaned with a disinfectant solution, and therefore the FPD needs to have waterproofing performance.

In this regard, Japanese Unexamined Patent Publication No. 2000-258541 discloses a configuration in which an O-ring serving as a waterproof member is interposed between the housing of the FPD and a detection surface cover portion.

Japanese Unexamined Patent Publication No. 2020-187054 discloses a configuration in which the housing of the FPD is divided into an incident-surface housing member, a side-surface housing member, and a rear-surface housing member, and a waterproof member formed of an elastic material such as rubber is interposed between the incident-surface housing member and the side-surface housing member and between the side-surface housing member and the rear-surface housing member.

### SUMMARY OF THE INVENTION

However, in the configuration in which a waterproof member, such as an O-ring, is sandwiched between housings (housing parts), it is necessary to fit the O-ring into a groove to prevent the O-ring from being displaced. In this case, a step of machining, with high accuracy, a groove for fitting the O-ring into the housing and a step of fitting the O-ring into the groove are required, thereby increasing the number of manufacturing steps for manufacturing the FPD.

On the other hand, when sheet-like rubber or closed-cell foamed resin is used as a waterproof member sandwiched between housings, it is not necessary to fit the waterproof member into a groove. However, when producing a frame-shaped member by punching out a central portion of sheet-like rubber or closed-cell foamed resin used as a waterproof member, the punched-out portion of the sheet has to be discarded, which poses problems in terms of the cost of the waterproof member, environmental impact, and the like.

Furthermore, in the configuration in which a waterproof member is sandwiched between housings, it is necessary to fasten the housings together with a screw in order to compress the waterproof member with the housings. In this case, a large number of screws are required to obtain sufficient compressive force to ensure waterproofing performance of the FPD. Furthermore, when the elasticity of the waterproof member is equal to or greater than a predetermined value, the housings are deformed by a reaction force from the waterproof member at locations away from the screws that fasten the housings together, and thus the waterproof member is insufficiently compressed. Therefore, it is necessary to suppress deformation of the housings by increasing the number of screws to reduce spacing between the screws. Therefore, an increase in the cost of the screws and an increase in steps to assemble the FPD using the screws have been problematic.

An object of the present disclosure is to provide a radiographic imaging apparatus capable of ensuring waterproofing performance while preventing an increase in processing cost into the housing, an increase in the number of components, and an increase in the number of steps for assembly.

To achieve at least one of the abovementioned objects, according to an aspect of the present disclosure, a radiographic imaging apparatus reflecting one aspect of the present disclosure includes:
a radiation detector including a photoelectric conversion element and a scintillator configured to convert radiation into light and irradiate the photoelectric conversion element with the light;
an electric circuit configured to drive the radiation detector and read out a signal of the photoelectric conversion element;
a housing including a front surface part on which the radiation is incident and a rear surface part facing the front surface part with the radiation detector interposed therebetween, the housing being configured to house the radiation detector and the electric circuit; and
a waterproof member disposed between the front surface part and the rear surface part,
wherein the waterproof member is a double-sided adhesive tape.

### BRIEF DESCRIPTION OF THE DRAWINGS

The advantages and features provided by one or more embodiments of the invention will become more fully understood from the detailed description given hereinafter and the appended drawings which are given by way of illustration only, and thus are not intended as a definition of the limits of the present disclosure, and wherein: FIG. 1 is a perspective view illustrating the exterior of a radiographic imaging apparatus according to a first embodiment;

FIG. 2 is a schematic sectional view of the radiographic imaging apparatus taken along line II-II in FIG. 1;

FIG. 3 is a view illustrating the outer edge of a cross section of the radiographic imaging apparatus taken along line II-II in FIG. 1;

FIG. 4 is a sectional view illustrating a configuration of waterproof tape;

FIG. 5 is a schematic view of the radiographic imaging apparatus according to the first embodiment, as viewed from a negative Z-axis direction through a back plate;

FIG. 6 is an enlarged view of a portion VI of FIG. 5;

FIG. 7A and FIG. 7B illustrate a state in which a gap at a seam between waterproof tapes is sealed by compression;

FIG. 8 is a view illustrating the outer edge of a cross section of the radiographic imaging apparatus according to a first modification example of the first embodiment taken along the line II-II;

FIG. 9 is a perspective view illustrating a corner of the radiographic imaging apparatus according to a second modification example of the first embodiment;

FIG. 10 is a plan view of the corner of the radiographic imaging apparatus according to the second modification example of the first embodiment, as viewed from the negative X-axis direction;

FIG. 11 is a perspective view illustrating the corner of the radiographic imaging apparatus according to a third modification example of the first embodiment;

FIG. 12 is a perspective view illustrating the corner of the radiographic imaging apparatus according to the third modification example of the first embodiment;

FIG. 13 is a perspective view illustrating the corner of the radiographic imaging apparatus according to a second embodiment;

FIG. 14A and FIG. 14B illustrate a state in which a gap at a seam between waterproof tapes is sealed by compression;

FIG. 15 is a sectional view illustrating the outer edge of the radiographic imaging apparatus according to a third embodiment;

FIG. 16 is a sectional view illustrating the outer edge of the radiographic imaging apparatus according to the third embodiment;

FIG. 17 is a rear view of the radiographic imaging apparatus having a side on which no screws are provided;

FIG. 18 is a schematic sectional view of the radiographic imaging apparatus taken along line XVIII-XVIII in FIG. 17; and

FIG. 19 illustrates a state of one-shot long-length imaging using a plurality of radiographic imaging apparatuses of FIG. 17.

### DETAILED DESCRIPTION

Hereinafter, one or more embodiments of the present disclosure will be described in detail with reference to the drawings. However, the scope of the invention is not limited to the disclosed embodiments or illustrated examples.

### First Embodiment

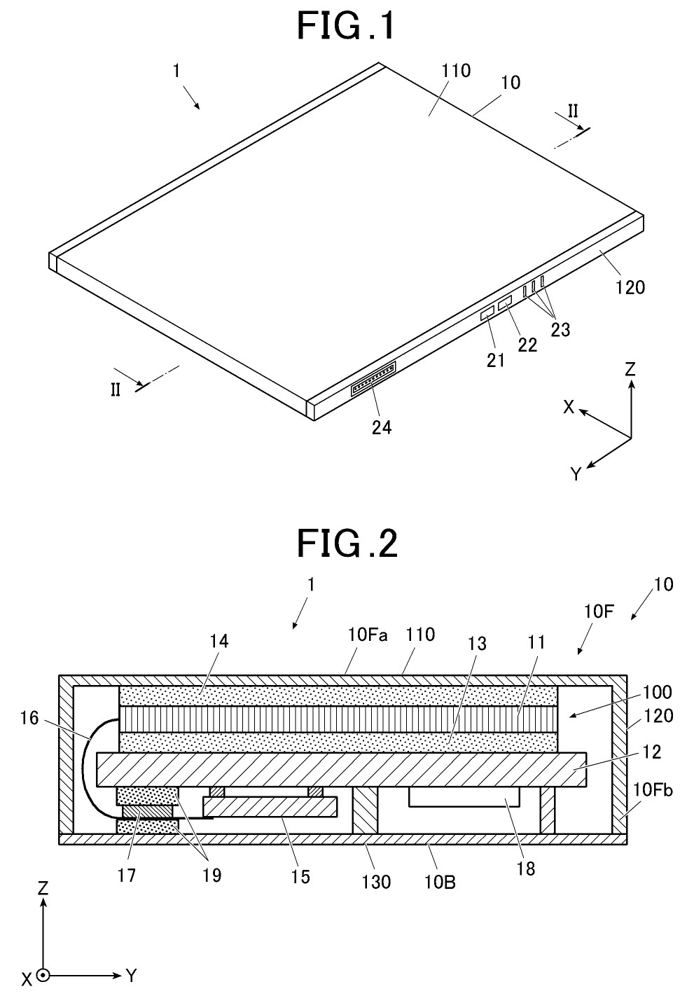

As shown in FIG. 1, a radiographic imaging apparatus 1 according to the present embodiment includes a housing 10. FIG. 1 is a perspective view of a radiation incident surface 110, which is a surface of the housing 10 on which radiation is incident, and a portion of a side surface 120. A surface opposite to the radiation incident surface 110 of the housing 10 is referred to as a rear surface 130 (see FIG. 2).

In FIG. 1, the X-axis direction is parallel to short sides of the housing 10. The Y-axis direction is parallel to long sides of the housing 10. The Z-axis direction is the thickness direction of the housing 10. For each axis, the direction indicated by the arrow is defined as the positive direction. That is, in the X-axis direction, the side on which a power switch 21, an operation switch 22, an indicator 23, and a connector 24 (described later) are provided is defined as the negative direction. In the Y-axis direction, a direction from the indicator 23 toward the connector 24 is defined as the positive direction. In the Z-axis direction, a direction from the rear surface 130 of the housing 10 toward the radiation incident surface 110 is defined as the positive direction.

FIG. 2 is a schematic sectional view of the radiographic imaging apparatus 1 taken along line II-II shown in FIG. 1.

As shown in FIG. 2, an internal module 100 is housed in the housing 10.

The radiographic imaging apparatus 1 includes a power switch 21, an operation switch 22, an indicator 23, and a connector 24 on a side surface 120 of the housing 10.

Connected to the connector 24 are a cable for communication between the radiographic imaging apparatus 1 and another device, a cable for charging the radiographic imaging apparatus 1, and the like.

The housing 10 is formed of, for example, carbon fiber reinforced resin (CFRP: Carbon Fiber Reinforced Plastics).

The housing 10 is divided into a box-shaped front plate 10F and a back plate 10B serving as a cover.

The front plate 10F includes a first front part 10Fa having a radiation incident surface 110, and second front parts 10Fb. The first front part 10Fa and the second front parts 10Fb are integrally formed.

The first front part 10Fa is formed in a rectangular plate-like shape.

Each second front part 10Fb extends from the peripheral edge of the first front part 10Fa in a direction orthogonal to the radiation incident surface 110 and toward a side on which the back plate 10B is present. The outer surface of the second front part 10Fb is the side surface 120 of the housing 10.

The back plate 10B faces the first front part 10Fa with the internal module 100 interposed therebetween, and extends parallel to the first front part 10Fa. The outer surface of the back plate 10B is the rear surface 130 of the housing 10.

The internal module 100 includes a radiation detection panel 11 (radiation detector), a support body 12, a first bonding member 13, a second bonding member 14, a circuit board 15, a chip-on-film (COF) 16, a readout IC 17, a rechargeable battery 18, a damping material 19, and the like.

The radiation detection panel 11 detects radiation transmitted through a subject and converts the radiation into radiographic image information.

The radiation detection panel 11 is of an indirect conversion type using photoelectric conversion elements (photodiodes) and a scintillator that converts radiation into light and irradiates the photoelectric conversion elements with the light. The photoelectric conversion elements constitute pixels together with thin film transistors (TFTs) for switching, and are formed two-dimensionally on a substrate.

The substrate of the radiation detection panel 11 is formed of glass for reasons such as accuracy stability and insulating properties.

When the radiation detection panel 11 is irradiated with radiation, the scintillator first emits light corresponding to the intensity of the radiation. Next, the photoelectric conversion elements on the substrate convert the light emitted by the scintillator into electric charges and output the electric charges as signals to the circuit board 15.

The radiation detection panel 11 may be a direct-conversion detection panel in which photoelectric conversion elements are provided on a substrate and a scintillator is not used.

The support body 12 is a support base material that supports the radiation detection panel 11, the circuit board 15, and the like.

The support body 12 supports the radiation detection panel 11 on a first surface, and supports the circuit board 15 on a second surface opposite the first surface.

The support body 12 may be fixed to the inner surface of the housing 10 with an adhesive or the like.

A positioning member (not shown) may be provided between the housing 10 and the support body 12 to prevent movement of the support body 12.

The substrate of the radiation detection panel 11 is formed of a brittle material (glass). Accordingly, the support body 12 for supporting the substrate is formed of a high-rigidity material. For example, the support body 12 is formed of CFRP or metal, each of which is a high-rigidity material. Accordingly, the robustness of the radiographic imaging apparatus 1 against loads, impacts, and the like can be improved. However, when metal is used as the material of the support body 12, an alloy of a light metal is preferably used for weight reduction because an increase in the weight of the apparatus increases the burden on the user. Examples of the light metal alloy include aluminum and magnesium.

The substrate of the radiation detection panel 11 may be formed of a flexible material such as polyimide resin. Accordingly, damage due to cracking of the substrate of the radiation detection panel 11 can be prevented. In this case, the support body 12 may be formed of foam of resin such as polystyrene. Accordingly, it is possible to further reduce the weight of the radiographic imaging apparatus 1.

The radiation detection panel 11 and the first surface of the support body 12 are fixed to each other by a first bonding member 13, with an electromagnetic shielding layer, a radiation shielding layer, a buffer layer, and the like (not shown) interposed therebetween.

The first bonding member 13 is an adhesive, double-sided adhesive tape, or the like, and fixes the radiation detection panel 11 and the support body 12 to each other.

The radiation detection panel 11 and the inner surface of the first front part 10Fa are fixed to each other by a second bonding member 14, with an electromagnetic shielding layer, a buffer layer, and the like (not shown) interposed therebetween.

The second bonding member 14 is an adhesive, double-sided adhesive tape, or the like, and fixes the radiation detection panel 11 and the first front part 10Fa to each other.

By using a peelable adhesive, double-sided adhesive tape, or the like as the second bonding member 14, the radiation detection panel 11 and the support body 12 may be removed from the housing 10.

By fixing the radiation detection panel 11 and the support body 12 to the housing 10 with the second bonding member 14, it is possible to suppress transmission of a drop impact from the side surface 120 to the radiation detection panel 11 and the support body 12. As a result, the robustness of the radiographic imaging apparatus 1 can be further improved.

The circuit board 15 forms an image based on the radiographic image information obtained by the conversion by the radiation detection panel 11. The circuit board 15 includes a processing circuit that includes a central processing unit (CPU), a read only memory (ROM), a random access memory (RAM), a communication section, and the like. The processing circuit controls driving of the radiation detection panel 11 and processes signals read out from the photoelectric conversion elements of the radiation detection panel 11. Specifically, the processing circuit generates image data from signals read out from the photoelectric conversion elements of the radiation detection panel 11, and outputs the image data to a console or the like (not shown).

The chip-on-film (COF) 16 is a flexible substrate that connects the radiation detection panel 11 and the circuit board 15.

The readout IC 17 is provided on the chip-on-film (COF) 16, and reads out signals from the radiation detection panel 11. The readout IC 17 functions as an electric circuit. The readout IC 17 A/D converts analog signals from the radiation detection panel 11 into digital signals.

A heat dissipation member (not shown) for dissipating heat generated by the readout IC 17 is provided in the vicinity of the readout IC 17.

The rechargeable battery 18 is a secondary battery that supplies power to the radiation detection panel 11, the circuit board 15, and the like. The rechargeable battery 18 is, for example, a lithium-ion capacitor, a lithium-ion battery, or the like.

The damping material 19 is provided between the readout IC 17 and the back plate 10B and between the readout IC 17 and the support body 12, thereby suppressing vibration transmitted to the readout IC 17. The damping material 19 may be omitted from between the readout IC 17 and the support body 12.

As the damping material 19 between the readout IC 17 and the back plate 10B, a heat-dissipating sheet having high thermal conductivity may be used to double as a heat dissipation member.

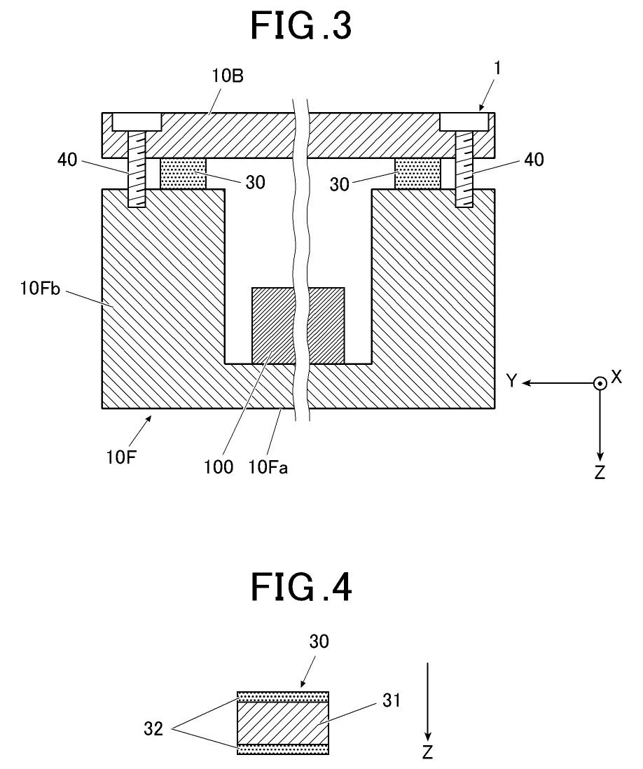

FIG. 3 is sectional view illustrating a configuration of the outer edge of the radiographic imaging apparatus 1. In FIG. 3, the back plate 10B is shown on the upper side of the drawing sheet, and the first front part 10Fa is shown on the lower side of the drawing sheet.

As shown in FIG. 3, a waterproof double-sided adhesive tape (hereinafter referred to as a waterproof tape 30) is interposed between each second front part 10Fb of the front plate 10F and the back plate 10B. The second front part 10Fb and the back plate 10B are bonded to each other by the waterproof tape 30. Further, at the outer peripheral side of a position where the waterproof tape 30 is disposed, a screw 40 is inserted from the back plate 10B side and screws the second front part 10Fb to the back plate 10B, thereby fixing the second front part 10Fb and the back plate 10B.

In the radiographic imaging apparatus 1, at least one screw 40 is disposed within a predetermined area from a corner of the housing 10.

As shown in FIG. 4, the waterproof tape 30 includes a tape base material 31 and an adhesive(s) 32 provided on both surfaces of the tape base material 31 in the Z-axis direction.

The tape base material 31 is formed of a material having waterproofing performance for being impermeable to water. Examples of the material having waterproofing performance include a nonwoven fabric and a foamed resin of a polyolefin or polyurethane.

The adhesive 32 is, for example, an acrylic adhesive.

The adhesive strength of the adhesive 32 is preferably not less than 6 N/cm and not more than 20 N/cm. Thus, after the waterproof tape 30 is attached to the second front part 10Fb of the front plate 10F and to the back plate 10B, the waterproof tape 30 brings the second front part 10Fb and the back plate 10B into close contact with each other without displacement. Therefore, the waterproofing performance of the radiographic imaging apparatus 1 can be ensured. Further, when the radiographic imaging apparatus 1 is disassembled for repair or the like, the waterproof tape 30 can be peeled off from the second front part 10Fb and the back plate 10B.

The adhesive strength of the adhesive 32 is preferably measured by the method described in JIS Z 0237.

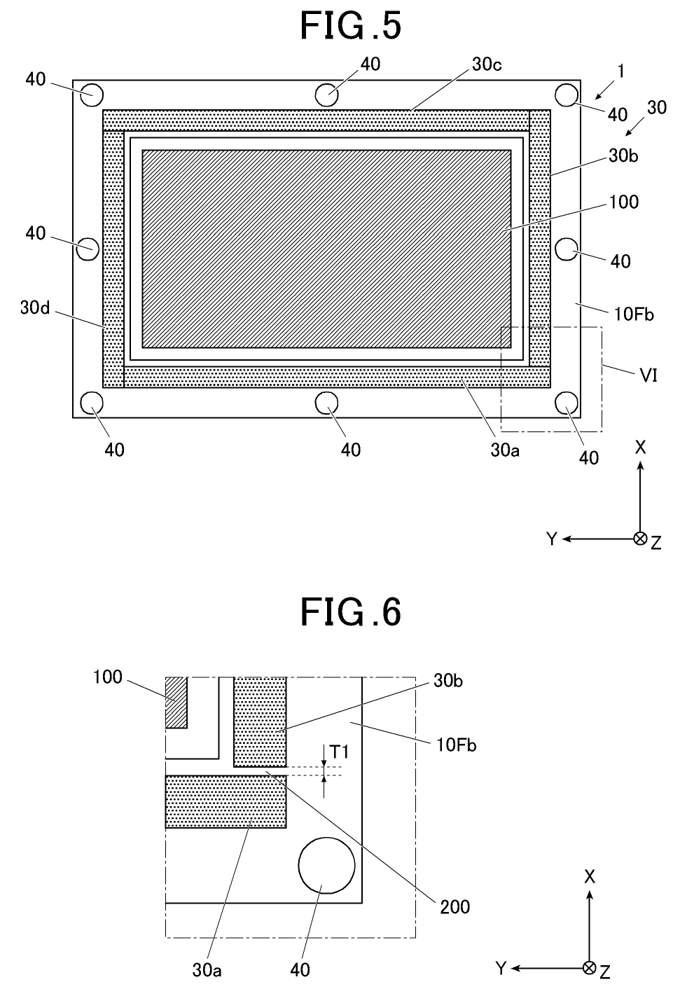

FIG. 5 is a plan view of the radiographic imaging apparatus 1 as viewed from the negative Z-axis direction through the back plate 10B.

As shown in FIG. 5, the waterproof tape 30 has an elongated shape in which the width of the tape is shorter than the length thereof. At the four sides defining, of the second front part 10Fb, the surface on the back plate 10B side, one waterproof tape 30 is disposed for each side along each side. That is, the waterproof tape 30, which is a double-sided adhesive tape, includes a plurality of elongated tape segments that are combined and arranged in a frame shape.

In other words, waterproof tapes 30 are disposed along the respective side walls (second front parts 10Fb) of the housing 10.

Specifically, waterproof tapes 30a and 30c, which constitute waterproof tape 30, are disposed along the long sides of the radiographic imaging apparatus 1, and waterproof tapes 30b and 30d, which constitute waterproof tape 30, are disposed along the short sides of the radiographic imaging apparatus 1.

The waterproof tape 30 is not limited to the shape shown in FIG. 5, and may have a shape corresponding to the shape of the housing 10, or may have a processed shape in which the tape width of a portion(s) of the waterproof tape 30 differs from that of the other portion(s), for example, to avoid the screw 40.

FIG. 6 is an enlarged view of a portion VI of FIG. 5.

As shown in FIG. 6, a seam 200 is formed between an end of a waterproof tape 30 (waterproof tape 30a in FIG. 6) disposed along a long side of the radiographic imaging apparatus 1 and an end of a waterproof tape 30 (waterproof tape 30b in FIG. 6) disposed along a short side of the radiographic imaging apparatus 1.

A gap T1 between the waterproof tapes 30 at the seam 200 is preferably 1 mm or less, and more preferably 0.5 mm or less.

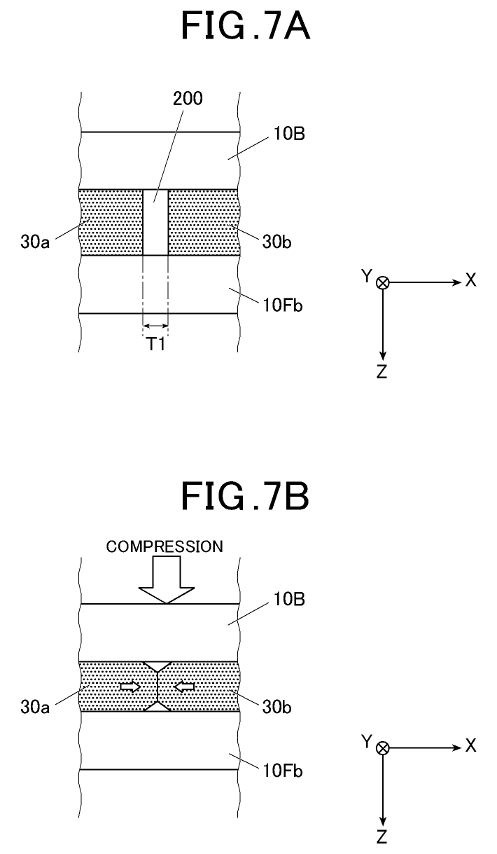

When the gap T1 is 1 mm or less, by tightening the screw 40 from the state shown in FIG. 7A to compress the waterproof tapes 30 in the Z-axis direction from the back plate 10B side, the waterproof tapes 30 are extruded into the gap T1 between the waterproof tapes 30, thereby sealing the gap T1 as shown in FIG. 7B.

The waterproof tapes 30 are preferably disposed such that the seam 200 is formed within a predetermined area from the arrangement position of the screw 40, which is in the vicinity of the screw 40. Accordingly, because a sufficient compressive force is obtained in the vicinity of the screw 40 by tightening the screw 40, the gap T1 can be sufficiently sealed by the waterproof tape 30.

The waterproof tape 30 preferably has a thickness of 0.1 mm to 2 mm, and more preferably 0.4 mm to 1 mm. If the waterproof tape 30 is too thick, a reaction force is generated when the waterproof tape 30 is compressed, and the housing 10 may be deformed by the reaction force. On the other hand, if the waterproof tape 30 is too thin, the waterproof tape 30 cannot be sufficiently compressed, and the gap T1 cannot be sufficiently sealed. Therefore, if the waterproof tape 30 is excessively thick or excessively thin, the waterproofing performance of the radiographic imaging apparatus 1 is reduced.

When the tape base material 31 is formed of a nonwoven fabric, the compression ratio of the waterproof tape 30 is preferably set such that the thickness of the waterproof tape 30 after compression is 80% or less of the thickness of the waterproof tape 30 before compression. When the tape base material 31 is formed of foam, the compression ratio of the waterproof tape 30 is preferably set such that the thickness of the waterproof tape 30 after compression is 50% or less of the thickness of the waterproof tape 30 before compression. By setting the compression ratio of the waterproof tape 30 to the above compression ratios, the gap T1 can be sufficiently sealed by the waterproof tape 30, thereby ensuring the waterproofing performance of the radiographic imaging apparatus 1 at the seam 200 between the waterproof tapes 30.

Although the first embodiment has been described above, the specific configuration is not limited to that of the first embodiment and may be modified without departing from the scope of the present disclosure. Hereinafter, modification examples of the first embodiment will be described. In the modification examples, the same components as those of the first embodiment are denoted by the same reference signs, and descriptions thereof are omitted.

### First Modification Example of First Embodiment

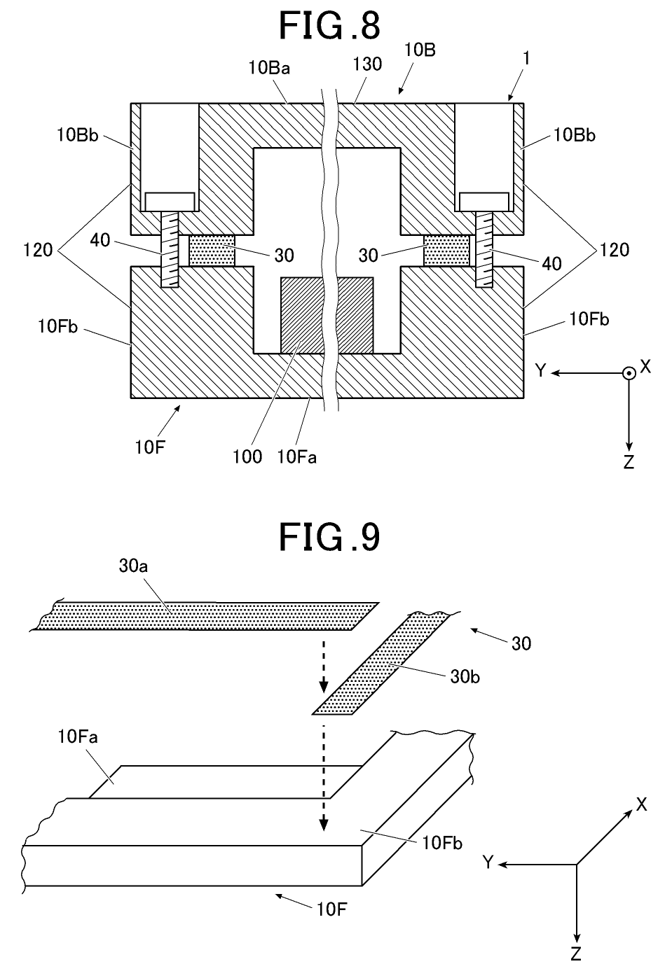

FIG. 8 is a sectional view illustrating the configuration of the outer edge of the radiographic imaging apparatus 1 according to a first modification example of the first embodiment.

The back plate 10B in the first modification example includes a first back part 10Ba and a second back part 10Bb. The first back part 10Ba and the second back part 10Bb are integrally formed.

The first back part 10Ba is formed in a rectangular plate shape. The outer surface of the first back part 10Ba is the rear surface 130 of the housing 10.

The second back part 10Bb extends from the peripheral edge of the first back part 10Ba in a direction orthogonal to the rear surface 130 and toward the front plate 10F.

In the first modification example, the length of the second front part 10Fb of the front plate 10F in the Z-axis direction is shorter than that in the first embodiment by an amount equal to the length of the second back part 10Bb of the back plate 10B in the Z-axis direction.

In the first modification example, the side surface 120 of the housing 10 is formed by the outer surface of the second front part 10Fb of the front plate 10F and the outer surface of the second back part 10Bb of the back plate 10B.

In the first modification example, the waterproof tape 30 is disposed between the second front part 10Fb of the front plate 10F and the second back part 10Bb of the back plate 10B. Thus, the second front part 10Fb and the second back part 10Bb are bonded together.

In the first modification example, a hole is formed in the first back part 10Ba and the screw 40 is recessed in the hole so that the head of the screw 40 does not protrude from the surface of the housing 10. The hole may be covered with a resin film, or a cap-shaped member made of resin, rubber, or the like and fitting the shape of the hole may be inserted into the hole, so that liquid or dirt does not accumulate in the hole.

### Second Modification Example of First Embodiment

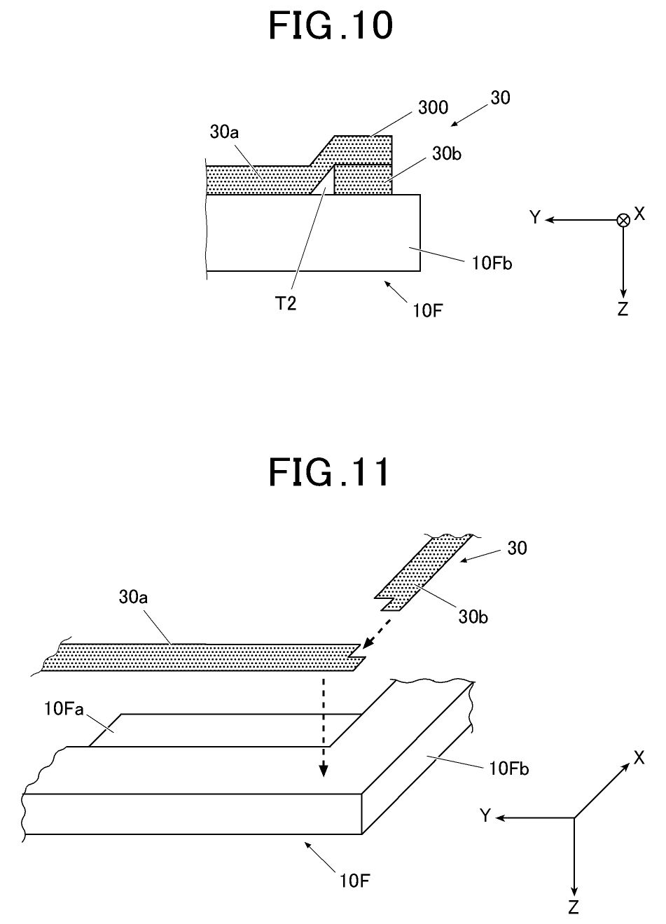

FIG. 9 and FIG. 10 are schematic views showing a corner of the radiographic imaging apparatus 1 according to a second modification example of the first embodiment. In FIS. 9 and FIG. 10, members other than the front plate 10F and the waterproof tape 30 are omitted.

In the waterproof tape 30 of the second modification example, as illustrated in FIG. 9 and FIG. 10, at a corner of the radiographic imaging apparatus 1, an end of the waterproof tape 30 disposed along a long side of the radiographic imaging apparatus 1 (waterproof tape 30a in FIG. 9 and FIG. 10) and an end of the waterproof tape 30 disposed along a short side of the radiographic imaging apparatus 1 (waterproof tape 30b in FIG. 9 and FIG. 10) are disposed so as to be stacked in the Z-axis direction. Accordingly, since no gap is formed at the seam between the waterproof tapes 30, the waterproofing performance of the radiographic imaging apparatus 1 at the seam between the waterproof tapes 30 can be ensured.

As shown in FIG. 10, a gap T2 is formed in the vicinity of an overlap portion 300 where ends of the waterproof tapes 30 are stacked in the Z-axis direction. However, by tightening the screw 40 to compress the waterproof tapes 30 in the Z-axis direction from the back plate 10B side, the waterproof tapes 30 are extruded into the gap T2, thereby sealing the gap T2.

The larger the area of the overlap portion 300, the larger the reaction force from the waterproof tapes 30 generated when the waterproof tapes 30 are compressed in the Z-axis direction from the back plate 10B side by tightening the screw 40. Therefore, the area of the overlap portion 300 is preferably equal to or less than the product of the widths of the waterproof tapes 30. Accordingly, a reaction force from the waterproof tapes 30 generated when the waterproof tapes 30 are compressed in the Z-axis direction from the back plate 10B side by tightening the screw 40 can be suppressed.

### Third Modification Example of First Embodiment

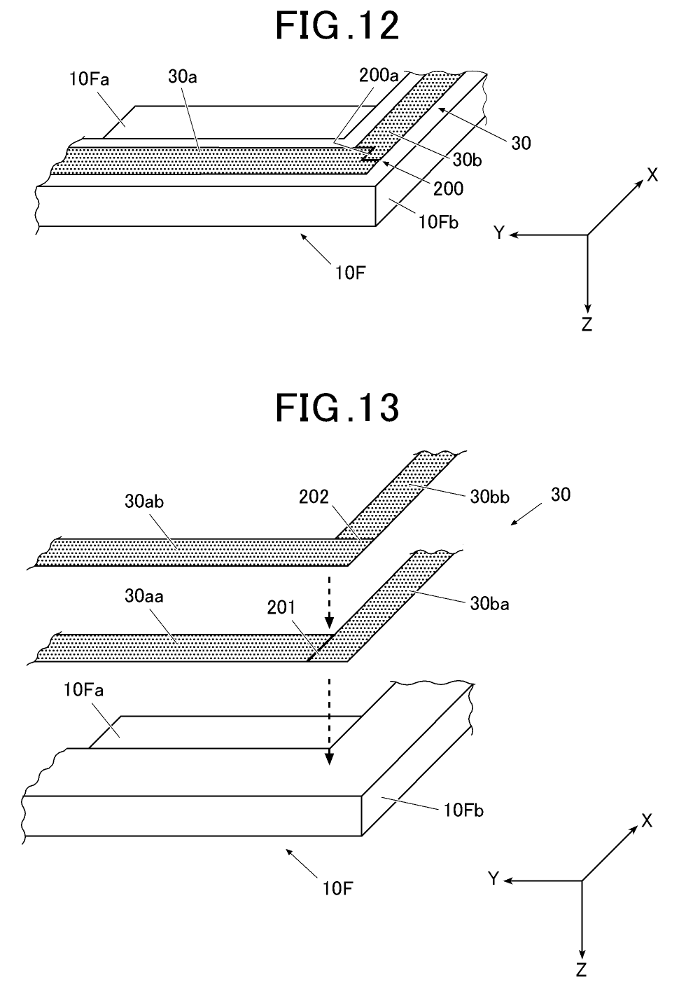

FIG. 11 and FIG. 12 are schematic views illustrating a corner of radiographic imaging apparatus 1 according to a third modification example of the first embodiment. In FIG. 11 and FIG. 12, members other than the front plate 10F and the waterproof tape 30 are omitted.

As shown in FIG. 11 and FIG. 12, at a corner of the radiographic imaging apparatus 1, a seam 200 is formed between an end of the waterproof tape 30 (waterproof tape 30a in FIG. 11 and FIG. 12) disposed along a long side of the radiographic imaging apparatus 1 and an end of the waterproof tape 30 (waterproof tape 30b in FIG. 11 and FIG. 12) disposed along a short side of the radiographic imaging apparatus 1.

In the third modification example, a path 200a connecting the outside and the inside of the housing 10 at the seam 200 has a so-called labyrinth structure.

In the third modification example, the length of the seam 200 on a plane orthogonal to the thickness direction (Z-axis direction) of the waterproof tape 30, i.e., the length of the path 200a connecting the outside and the inside of the housing 10 at the seam 200, is greater than the tape width of the waterproof tape 30.

Accordingly, since a path through which a liquid or the like enters the inside of the housing 10 from the outside can be further lengthened, the waterproofing performance of the radiographic imaging apparatus 1 can be improved.

### Second Embodiment

Next, a second embodiment will be described. Hereinafter, differences from the above-described first embodiment will be mainly described.

FIG. 13 is a schematic diagram illustrating a corner of the radiographic imaging apparatus 1 according to a second embodiment. In FIG. 13, members other than the front plate 10F and the waterproof tape 30 are omitted.

In the second embodiment, the waterproof tape 30 has a laminated structure of two layers stacked over the entirety thereof in the Z-axis direction. The waterproof tape 30 may have a laminated structure of three or more layers stacked over the entirety thereof in the Z-axis direction.

A seam 201 is formed between an end of a first layer of the waterproof tape 30 (waterproof tape 30aa in FIG. 13) disposed along a long side of the radiographic imaging apparatus 1 and an end of a first layer of the waterproof tape 30 (waterproof tape 30ba in FIG. 13) disposed along a short side of the radiographic imaging apparatus 1.

A seam 202 is formed between an end of a second layer of the waterproof tape 30 (waterproof tape 30ab in FIG. 13) disposed along the long side of the radiographic imaging apparatus 1 and an end of a second layer of the waterproof tape 30 (waterproof tape 30bb in FIG. 13) disposed along the short side of the radiographic imaging apparatus 1.

The waterproof tapes 30 according to the second embodiment are disposed such that the seam 201 and the seam 202 do not overlap each other in the thickness direction (Z-axis direction) of the waterproof tapes 30.

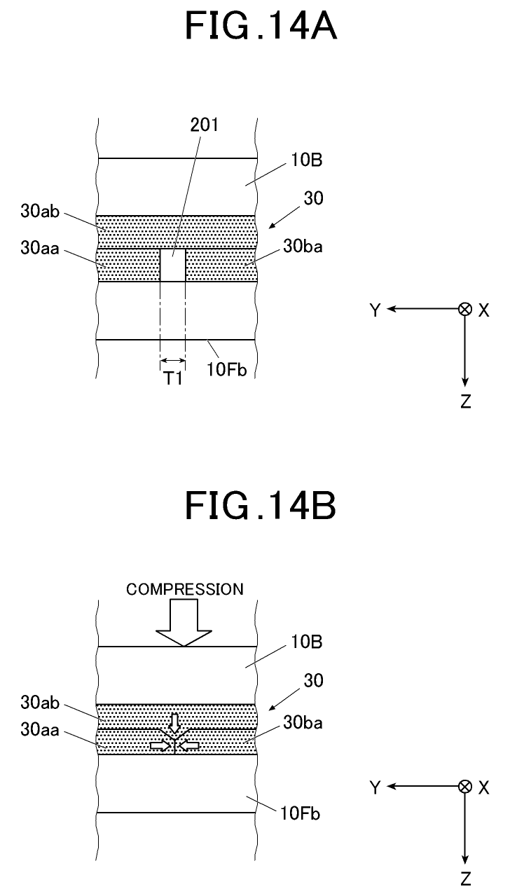

By tightening the screw 40 from the state shown in FIG. 14A to compress the waterproof tapes 30 in the Z-axis direction from the back plate 10B side, the waterproof tapes 30 are extruded into the gap T1 between the waterproof tapes 30, thereby sealing the gap T1 as shown in FIG. 14B.

In the second embodiment, since the waterproof tapes 30 have a two-layer laminated structure, when the waterproof tapes 30 are compressed, the waterproof tapes 30 (waterproof tapes 30aa and 30ba in FIG. 14) that form the seam (seam 201 in FIG. 14A and FIG. 14B) and the waterproof tape 30 (waterproof tape 30ab in FIG. 14A and FIG. 14B) other than the waterproof tapes 30 forming the seam are extruded into the gap T1 by compression.

That is, into the gap at the seam between the waterproof tapes 30, the waterproof tapes 30 are extruded from three directions upon compression of the waterproof tapes 30, thereby sealing the gap. Accordingly, the waterproofing performance of the radiographic imaging apparatus 1 is further improved. In the example shown in FIG. 14B, due to compression of the waterproof tapes 30, into the gap T1, the waterproof tape 30aa is extruded from the positive Y-axis side, the waterproof tape 30ba is extruded from the negative Y-axis side, and the waterproof tape 30ab is extruded from the negative Z-axis side.

In the first embodiment and the second embodiment, examples have been described in which the waterproofing performance of the radiographic imaging apparatus 1 is ensured by extruding, through compression, the waterproof tapes 30 each including the tape base material 31 and the adhesive 32 into the gap at the seam between the waterproof tapes 30, thereby sealing the gap; however, the present invention is not limited thereto.

The waterproof tape 30 may be a base-material-less tape that does not include the tape base material 31 and is composed only of the adhesive 32. In this case, the adhesives 32 of the waterproof tapes 30 are extruded by compression into the gap at the seam between the waterproof tapes 30, thereby sealing the gap. Accordingly, the waterproofing performance of the radiographic imaging apparatus 1 can be sufficiently ensured.

When the waterproof tape 30 is a thin tape (e.g., having a thickness of less than 0.1 mm), a predetermined number of waterproof tapes 30 are stacked and arranged overall in the thickness direction (Z-axis direction) of the waterproof tape 30, so that the thickness of the stacked waterproof tapes 30 can be a predetermined thickness (e.g., 0.1 mm or more). Accordingly, the waterproofing performance of the radiographic imaging apparatus 1 can be sufficiently ensured.

As in the second embodiment, the waterproof tape 30 in the first embodiment may have a laminated structure of two or more layers stacked overall in the thickness direction (Z-axis direction) of the waterproof tape 30.

### Third Embodiment

Next, a third embodiment will be described. Hereinafter, differences from the above-described first embodiment will be mainly described.

Ethanol that is a disinfectant solution used in an environment where the radiographic imaging apparatus 1 is used also acts as an organic solvent. Therefore, the adhesive 32 of the waterproof tape 30, which is an organic compound, deteriorates when exposed to a large amount of ethanol for a long period of time. When the adhesive 32 deteriorates, the waterproofing performance of the radiographic imaging apparatus 1 may decrease.

To address this problem, the radiographic imaging apparatus 1 according to the third embodiment includes a protective member that protects at least the adhesive 32 of the waterproof tape 30.

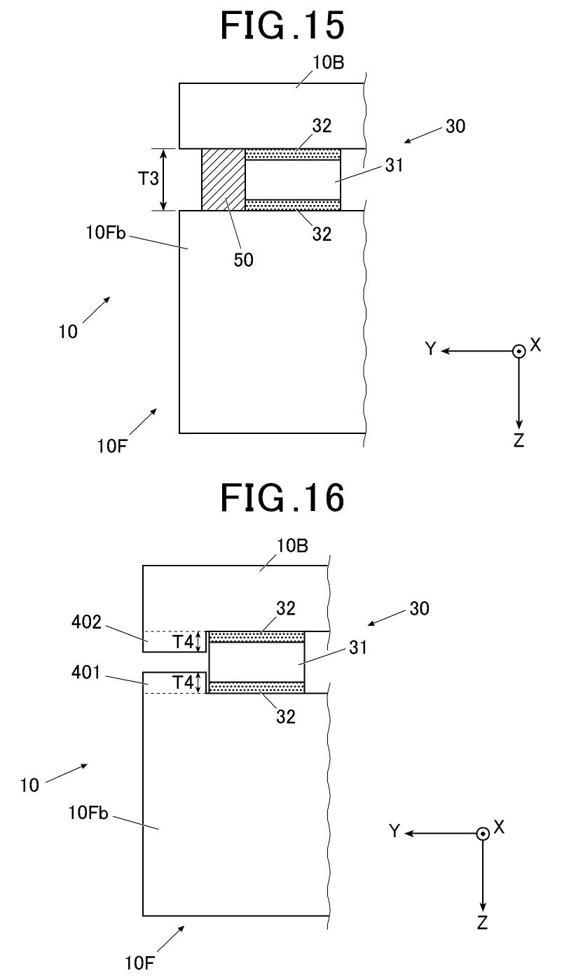

FIG. 15 is a sectional view illustrating the configuration of the outer edge of the radiographic imaging apparatus 1 according to the third embodiment.

As shown in FIG. 15, the radiographic imaging apparatus 1 according to the third embodiment includes a filler 50 as a protective member configured to protect the waterproof tape 30 so that a liquid entering the inside of the housing 10 from the outside through a gap T3 between the second front part 10Fb of the front plate 10F and the back plate 10B does not contact the waterproof tape 30.

The filler 50 is in a liquid or gel form, and is applied to the outer periphery (side surface) of the waterproof tape 30 after a step of sandwiching the waterproof tape 30 between the second front part 10Fb of the front plate 10F and the back plate 10B.

The filler 50 cures into a rubbery state over time. Thus, the cured filler 50 can protect the waterproof tape 30 so that liquid entering the housing 10 from the outside through the gap T3 between the second front part 10Fb of the front plate 10F and the back plate 10B does not contact the waterproof tape 30.

As illustrated in FIG. 16, the radiographic imaging apparatus 1 according to the third embodiment may include steps 401, 402 as protective members configured to protect at least the adhesive 32 so that a liquid entering the inside of the housing 10 from the outside through a gap between the second front part 10Fb of the front plate 10F and the back plate 10B does not contact the adhesive 32.

The step 401 is provided to protrude from an end of the second front part 10Fb on the back plate 10B side toward the back plate 10B.

The step 402 is provided on the back plate 10B so as to protrude toward the second front part 10Fb at a position facing the step 401.

The configuration in which the step 401 is provided on the second front part 10Fb and the step 402 is provided on the back plate 10B can be machined more easily than a configuration in which grooves for placing the waterproof tape 30 are provided in the second front part 10Fb and the back plate 10B. In addition, the steps 401, 402 facilitate positioning of the waterproof tape 30 when the waterproof tape 30 is attached to the second front part 10Fb and the back plate 10B. Therefore, the radiographic imaging apparatus 1 can be easily manufactured.

A protruding length T4 protruding in the Z-axis direction, which is the height of the steps 401, 402, is greater than the thickness of the adhesive 32 of the waterproof tape 30 and less than the thickness of the waterproof tape 30.

Thus, even if liquid enters the inside of the housing 10 from the outside through the gap between the second front part 10Fb and the back plate 10B, the adhesive 32 can be prevented from coming into contact with the liquid.

The amount by which the waterproof tape 30 is compressed in the Z-axis direction can be adjusted according to the height of the steps 401, 402. Therefore, by setting the amount by which the waterproof tape 30 is compressed in the Z-axis direction to an appropriate value, variations in the waterproofing performance of the radiographic imaging apparatus 1 can be suppressed.

### Others

As described in the above embodiment(s), use of the waterproof tape 30 to bond the front plate 10F and the back plate 10B enables a reduction in the number of screws 40 for fixing the front plate 10F and the back plate 10B, as compared with a conventional radiographic imaging apparatus.

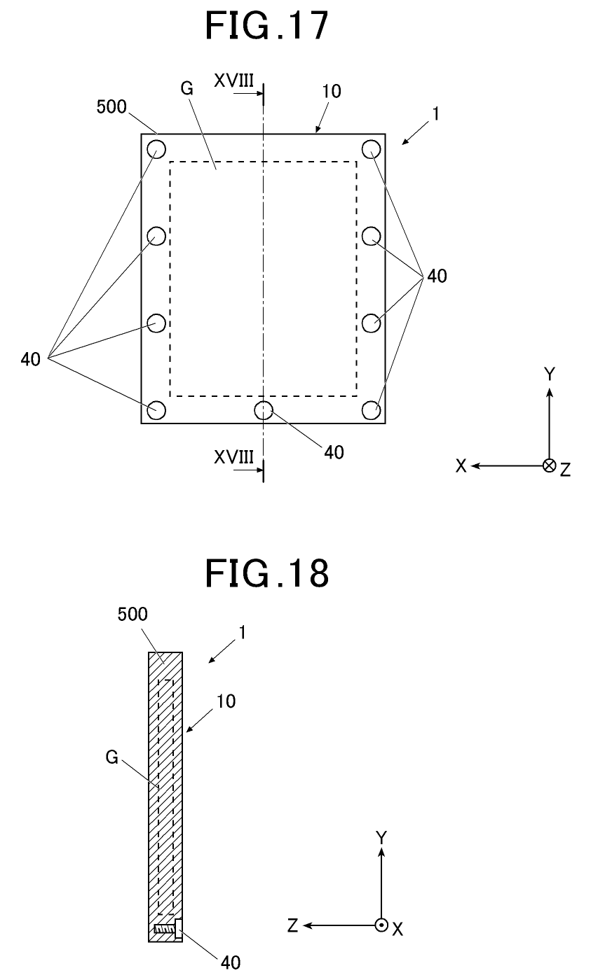

FIG. 17 is a schematic view of the radiographic imaging apparatus 1 with a reduced number of screws 40. FIG. 18 is a schematic sectional view of the radiographic imaging apparatus 1 taken along line XVIII-XVIII shown in FIG. 17. In FIG. 18, members other than the housing 10 and the screws 40 are omitted.

In the radiographic imaging apparatus 1, it is unnecessary to compress the heat dissipation member on a side on which the readout IC 17 is not disposed. For example, in FIG. 17, the side on which the readout IC 17 is not disposed is a first side 500, which is a short side on the positive Y-axis direction side. Accordingly, on the first side 500, the number of screws 40 can be reduced over the width of an effective image region G of the radiation detection panel 11, excluding the corners of the housing 10.

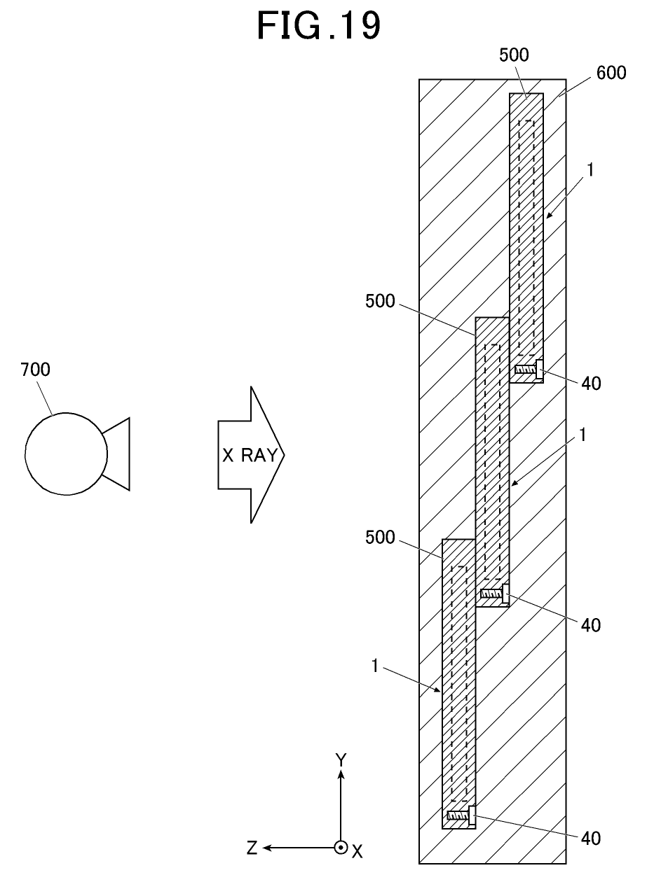

FIG. 19 shows an example of the radiographic imaging apparatus 1 in which the number of screws 40 is reduced for one-shot long-length imaging, which is a method for imaging a relatively wide area such as the upper body, the lower body, or the like of a patient.

In the one-shot long-length imaging, two or more radiographic imaging apparatuses 1 are arranged in an long holder 600 so as to overlap in the direction of the body axis of a subject.

In the present embodiment, the radiographic imaging apparatuses 1 are arranged such that the first sides 500 of the radiographic imaging apparatuses 1 are positioned on a side where a tube 700 that generates radiation is disposed. Accordingly, since the screws 40 can be prevented from appearing in a radiographic image generated by the radiographic imaging apparatuses 1, the influence of the screws 40 on diagnosis of the radiographic image can be eliminated.

In the radiographic imaging apparatus 1 having a reduced number of screws 40, a marking may be provided on the first side 500 so that the user of the radiographic imaging apparatus 1 can visually recognize the first side 500. In the radiographic imaging apparatus 1 with a reduced number of screws 40, the first side 500 may be surface-treated so that the user of the radiographic imaging apparatus 1 can recognize the first side 500 by touch.

The shape of a storage section of the long holder 600 configured to store a radiographic imaging apparatus 1 may be a shape on conformity with the positional relationship between the connector 24 and the first side 500 in the radiographic imaging apparatus 1.

For example, in the case where the radiographic imaging apparatus 1 is inserted into the storage section of the long holder 600 in an opposite orientation in the Y-axis direction, that is, when the radiographic imaging apparatus 1 is arranged such that the first side 500 is positioned on the opposite side of the tube 700 as compared with another radiographic imaging apparatuses 1, if the storage section of the long holder 600 has a shape that prevents a cable from being connected to the connector 24, the one-shot long-length imaging can be prevented from being performed in the state in which the radiographic imaging apparatus 1 is inserted in the opposite orientation.

Accordingly, the first side 500 can be reliably arranged so as to be positioned closer to the tube 700 side than another radiographic imaging apparatus 1.

As described above, the radiographic imaging apparatus 1 according to the present embodiment(s) includes the radiation detector (radiation detection panel 11) including the photoelectric conversion element(s) and the scintillator configured to convert radiation into light and to irradiate the photoelectric conversion element with the light.

The radiographic imaging apparatus 1 according to the present embodiment includes the electric circuit (circuit board 15, readout IC 17) configured to drive the radiation detector and to read out a signal from the photoelectric conversion element.

The radiographic imaging apparatus 1 according to the present embodiment includes the housing 10 having the front surface part (front plate 10F) on which radiation is incident and the rear surface part (back plate 10B) facing the first front part 10Fa with the radiation detector interposed therebetween, the housing 10 housing the radiation detector and the electric circuit.

The radiographic imaging apparatus 1 according to the present embodiment includes the waterproof member (waterproof tape 30) disposed between the front surface part and the rear surface part.

### The waterproof member is double-sided adhesive tape.

Accordingly, as the waterproof member to be interposed between the housing parts of the FPD (radiographic imaging apparatus 1), the waterproof tape 30 composed of elongated double-sided adhesive tapes combined and arranged in a frame shape can be used. Accordingly, the FPD can be readily manufactured, and the cost of the waterproof member can be reduced. Since waste generated in manufacturing the waterproof member can be reduced, the environmental impact can be suppressed. Since the double-sided adhesive tape itself serving as the waterproof tape 30 has adhesiveness, it is unnecessary to form, in the housing, a groove for preventing the double-sided adhesive tape from shifting in position. By entering minute surface irregularities on the surface of the housing 10, the adhesive 32 of the waterproof tape 30 can prevent liquid from entering the inside of the housing 10 from the outside. Thus, the compression amount of the waterproof member required to bring the waterproof member into close contact with the housing can be reduced. Accordingly, the number of screws for coupling the housings (housing parts) can be reduced, and the cost of the screws and the number of steps for assembling the FPD using the screws can be reduced.

Accordingly, the waterproofing performance of the radiographic imaging apparatus 1 can be ensured while increases in the processing cost into the housing, in the number of components, and in the number of steps for assembly.

In the radiographic imaging apparatus 1 according to the present embodiment, the double-sided adhesive tape (waterproof tape 30) includes the base material (tape base material 31) and the adhesive 32 provided on both surfaces of the base material.

In the radiographic imaging apparatus 1 according to the present embodiment, the adhesive strength of the adhesive 32 is not less than 6 N/cm and not greater than 20 N/cm.

Accordingly, after the waterproof tape 30 is attached to the second front part 10Fb and the back plate 10B, the waterproof tape 30 keeps the second front part 10Fb and the back plate 10B in close contact without displacement, thereby ensuring the waterproofing performance of the radiographic imaging apparatus 1. Further, when the radiographic imaging apparatus 1 is disassembled for repair or the like, the waterproof tape 30 can be peeled off from the second front part 10Fb and the back plate 10B.

In the radiographic imaging apparatus 1 according to the present embodiment, the double-sided adhesive tape (waterproof tape 30) includes a plurality of double-sided adhesive tapes, each having an elongated shape in which the width is shorter than the length.

The double-sided adhesive tapes are arranged along respective side walls (second front parts 10Fb) of the housing 10.

The seam 200 between the double-sided adhesive tapes is disposed within a predetermined area from the position at which the screw 40 for fastening the front surface part (front plate 10F) and the rear surface part (back plate 10B) is disposed.

Accordingly, because a sufficient compressive force is obtained in the vicinity of the screw 40 by tightening the screw 40, the gap T1 can be sufficiently sealed by the waterproof tape 30.

In the radiographic imaging apparatus 1 according to the present embodiment, the screw 40 is disposed within a predetermined area from a corner of the housing 10.

Accordingly, since the front plate 10F and the back plate 10B can be reliably fixed to each other at the corner of the housing 10, displacement between the front plate 10F and the back plate 10B can be suppressed.

In the radiographic imaging apparatus 1 according to the present embodiment, the length of the seam 200 between the double-sided adhesive tapes (waterproof tapes 30) on the plane orthogonal to the thickness direction (Z-axis direction) of the double-sided adhesive tapes is greater than the width of the double-sided adhesive tapes.

Accordingly, since a path through which a liquid or the like enters the inside of the housing 10 from the outside can be further lengthened, the waterproofing performance of the radiographic imaging apparatus 1 can be improved.

The radiographic imaging apparatus 1 according to the present embodiment includes the overlap portion 300 in which an end of one double-sided adhesive tape and an end of another double-sided adhesive tape are stacked.

The area of the overlap portion 300 is not greater than the product of widths of the double-sided adhesive tapes whose ends are stacked.

Accordingly, a reaction force from the waterproof tape(s) 30 generated when the waterproof tape 30 is compressed in the Z-axis direction from the back plate 10B side by tightening the screw 40 can be suppressed.

The radiographic imaging apparatus 1 according to the present embodiment includes a plurality of elongated double-sided adhesive tapes (waterproof tapes 30) each having an elongated shape in which the width is shorter than the length.

The double-sided adhesive tapes each have a laminated structure of two or more layers stacked and are arranged along respective side walls (second front parts 10Fb) of the housing 10.

The seam 201 between the double-sided adhesive tapes in one layer and the seam 202 between the double-sided adhesive tapes in another layer are arranged so as not to overlap each other in the thickness direction (Z-axis direction) of the double-sided adhesive tapes.

Accordingly, in response to compression of the waterproof tapes 30, the waterproof tapes 30 are pushed out into a gap at a seam between the waterproof tapes 30 from three directions, thereby sealing the gap. Accordingly, the waterproofing performance of the radiographic imaging apparatus 1 is further improved.

The radiographic imaging apparatus 1 according to the present embodiment includes the protective member provided on a side surface of the double-sided adhesive tape(s) (waterproof tape(s) 30) so as to cover at least the adhesive(s) 32.

Thus, even if liquid enters the inside of the housing 10 from the outside, contact of the liquid with the adhesive 32 can be prevented. Therefore, deterioration of the adhesive 32 can be suppressed, and a decrease in the waterproofing performance of the radiographic imaging apparatus 1 can be prevented.

In the radiographic imaging apparatus 1 according to the present embodiment, the protective member is a portion (step 401, step 402) formed by a part of the housing 10 protruding so as to cover at least the adhesive 32 on the side surface of the double-sided adhesive tape (waterproof tape 30).

The steps 401, 402 can be machined more easily than forming grooves in the second front part 10Fb and the back plate 10B for placing the waterproof tape 30. In addition, the steps 401, 402 facilitate positioning of the waterproof tape 30 when the waterproof tape 30 is attached to the second front part 10Fb and the back plate 10B. Therefore, the radiographic imaging apparatus 1 can be easily manufactured.

Further, the amount by which the waterproof tape 30 is compressed in the Z-axis direction can be adjusted according to the height of the steps 401, 402. Therefore, by setting the amount by which the waterproof tape 30 is compressed in the Z-axis direction to an appropriate value, variations in the waterproofing performance of the radiographic imaging apparatus 1 can be suppressed.

In the radiographic imaging apparatus 1 according to the present embodiment, the protruding length of the protective member (step 401, step 402) is greater than the thickness of the adhesive 32 and less than the thickness of the double-sided adhesive tape (waterproof tape 30).

Thus, even if liquid enters the inside of the housing 10 from the outside through the gap between the second front part 10Fb and the back plate 10B, the adhesive 32 acn be prevented from coming into contact with the liquid.

In the radiographic imaging apparatus 1 according to the present embodiment, the protective member is the filler 50.

Thus, the waterproof tape 30 can be protected from coming into contact with liquid that enters the housing 10 from the outside through the gap T3 between the second front part 10Fb of the front plate 10F and the back plate 10B.

Although some embodiments according to the present disclosure have been described above in detail, the present disclosure is not limited to the above-described embodiments, and may be modified without departing from the scope of the present disclosure.

For example, the adhesive 32 of the waterproof tape 30 may be formed of a material capable of reducing the adhesive strength of the adhesive 32 when the adhesive 32 is heated or when an electric current is applied to the adhesive 32. In the case where the waterproof tape 30 includes the adhesive 32 having such a function, the adhesive strength of the adhesive 32 may be greater than 20 N/cm. In this case, when the radiographic imaging apparatus 1 is disassembled for repair or the like, the adhesive strength of the adhesive 32 is reduced to 20 N/cm or less by heating the adhesive 32 or applying an electric current to the adhesive 32. Thus, the waterproof tape 30 can be easily peeled off from the second front part 10Fb and the back plate 10B.

Further, the adhesive 32 of the waterproof tape 30 may have a smaller adhesive strength on one surface than on the other surface. Alternatively, the adhesive strength reducing function may be provided only on one surface of the waterproof tape 30. Thus, when the waterproof tape 30 is peeled off, the waterproof tape 30 can be peeled off from a desired adhesive surface.

In addition, detailed configurations of respective members constituting the radiographic imaging apparatus can be changed as appropriate without departing from the scope of the present disclosure.

Although embodiments of the present disclosure have been described and illustrated in detail, the disclosed embodiments are made for purposes of illustration and example only and not limitation. The scope of the present disclosure should be interpreted by terms of the appended claims.

What is claimed is:

1. A radiographic imaging apparatus comprising:
a radiation detector including a photoelectric conversion element and a scintillator configured to convert radiation into light and irradiate the photoelectric conversion element with the light;
an electric circuit configured to drive the radiation detector and read out a signal of the photoelectric conversion element;
a housing including a front surface part on which the radiation is incident and a rear surface part facing the front surface part with the radiation detector interposed therebetween, the housing being configured to house the radiation detector and the electric circuit; and
a waterproof member disposed between the front surface part and the rear surface part,
wherein the waterproof member is a double-sided adhesive tape.

2. The radiographic imaging apparatus according to claim 1, wherein the double-sided adhesive tape includes a base material and an adhesive provided on both surfaces of the base material.

3. The radiographic imaging apparatus according to claim 2, wherein an adhesive strength of the adhesive is not less than 6 N/cm and not more than 20 N/cm.

4. The radiographic imaging apparatus according to claim 1,
wherein the double-sided adhesive tape includes double-sided adhesive tapes each having an elongated shape in which a width is shorter than a length,
wherein the double-sided adhesive tapes are disposed along respective side walls of the housing, and
wherein a seam between the double-sided adhesive tapes is disposed within a predetermined area from a position where a screw that fastens the front surface part and the rear surface part is disposed.

5. The radiographic imaging apparatus according to claim 4, wherein the screw is disposed within a predetermined area from a corner of the housing.

6. The radiographic imaging apparatus according to claim 4, wherein a length of the seam between the double-sided adhesive tapes on a plane orthogonal to a thickness direction of the double-sided adhesive tapes is greater than a width of the double-sided adhesive tapes.

7. The radiographic imaging apparatus according to claim 4, further comprising an overlap portion where an end of one of the double-sided adhesive tapes and an end of another one of the double-sided adhesive tapes are stacked,
wherein an area of the overlap portion is equal to or less than a product of widths of the double-sided adhesive tapes whose ends are stacked.

8. The radiographic imaging apparatus according to claim 1,
wherein the double-sided adhesive tape includes double-sided adhesive tapes each having an elongated shape in which a width is shorter than a length,
wherein the double-sided adhesive tapes each have a laminated structure in which two or more layers are stacked, and are disposed along respective side walls of the housing, and
wherein a seam between the double-sided adhesive tapes in one layer of the layers and a seam between the double-sided adhesive tapes in another layer of the layers are disposed so as not to overlap in a thickness direction of the double-sided adhesive tapes.

9. The radiographic imaging apparatus according to claim 2, further comprising a protective member provided so as to cover at least the adhesive on a side surface of the double-sided adhesive tape.

10. The radiographic imaging apparatus according to claim 9, wherein the protective member is a portion of the housing protruding so as to cover at least the adhesive on the side surface of the double-sided adhesive tape.

11. The radiographic imaging apparatus according to claim 10, wherein a protruding length of the protective member is greater than a thickness of the adhesive and less than a thickness of the double-sided adhesive tape.

12. The radiographic imaging apparatus according to claim 9, wherein the protective member is a filler.
